(19) United States
(12) Patent Application Publication
(10) Pub. No.: US 2024/0170480 A1
(43) Pub. Date: May 23, 2024

(54) SEMICONDUCTOR DEVICE

(71) Applicant: Renesas Electronics Corporation, Tokyo (JP)

(72) Inventor: Taishu OYAMA, Tokyo (JP)

(21) Appl. No.: 18/512,855

(22) Filed: Nov. 17, 2023

(30) Foreign Application Priority Data
Nov. 18, 2022 (JP) 2022-184566

(51) Int. Cl. H01L 27/02; H01L 27/06

(52) U.S. Cl. CPC H01L 27/0296; H01L 27/0623

(57) ABSTRACT

A semiconductor device includes a first semiconductor element that is an N-channel type MOSFET, a second semiconductor element that is an N-channel type MOSFET disposed next to the first semiconductor element, and a DTI that surrounds the first semiconductor element and the second semiconductor element, the first semiconductor element is connected to a first circuit and the second semiconductor element is connected to a second circuit different from the first circuit.

### CROSS-REFERENCE TO RELATED APPLICATIONS

The disclosure of Japanese Patent Application No. 2022-184566 filed on Nov. 18, 2022, including the specification, drawings and abstract is incorporated herein by reference in its entirety.

### BACKGROUND

The present disclosure relates to a semiconductor device.

There is a disclosed technique listed below.

### [Patent Document 1] Japanese Unexamined Patent Application Publication No. 2017-183403

Developments have been made on a deep trench isolation. Patent Document 1 describes a semiconductor device in which malfunction of a semiconductor element due to a leakage current caused by a variation in oxygen concentration in a semiconductor substrate is suppressed, and describes a manufacturing method of the semiconductor device. Patent Document 1 describes the semiconductor device in which a high withstand voltage NMOS transistor formation region defined by an element isolation insulating film (deep trench isolation), a CMOS transistor formation region defined by an element isolation insulating film, and a substrate contact portion are formed.

### SUMMARY

However, a stress of DTI (Deep Trench Isolation) may deteriorate the performance of MOSFET (Metal Oxide Semiconductor Field Effect Transistor). Therefore, an object of the present disclosure is to provide a semiconductor device in which elements are disposed so as to prevent adverse effects of DTI stress. Other objects and novel features will become apparent from the description of this specification and the accompanying drawings.

According to one embodiment, the high performance transistor is disposed away from the DTI to effectively utilize the open space.

According to the embodiment, a semiconductor device in which elements are disposed so as to prevent the adverse effects of DTI stress can be provided.

### BRIEF DESCRIPTION OF THE DRAWINGS

FIG. 1 is a schematic plan view of a deep trench isolation according to an embodiment.

FIG. 2 is a diagram showing a stress of the deep trench isolation and an effect of the stress on a MOS transistor according to the embodiment.

FIG. 3 is a layout diagram of the semiconductor device according to a first embodiment.

FIG. 4 is a diagram showing an exemplary configuration of a pair transistor according to the first embodiment.

FIG. 5 is a diagram showing a manufacturing method of the pair transistor according to the first embodiment.

FIG. 6 is a layout diagram of a semiconductor device according to a second embodiment.

FIG. 7 is a layout diagram of a semiconductor device according to a third embodiment.

FIG. 8 is a layout diagram of a semiconductor device according to a fourth embodiment.

FIG. 9 is a layout diagram of a semiconductor device according to a fifth embodiment.

FIG. 10 is a layout diagram of a semiconductor device according to a sixth embodiment.

FIG. 11 is a modified example of the layout of the deep trench isolation according to the embodiment.

### DETAILED DESCRIPTION

### Embodiment

For clarity of explanation, the following description and drawings are appropriately omitted and simplified. In the drawings, the same elements are denoted by the same reference numerals, and a repetitive description thereof is omitted as necessary.

### Explanation of Deep Trench Isolation According to Embodiment

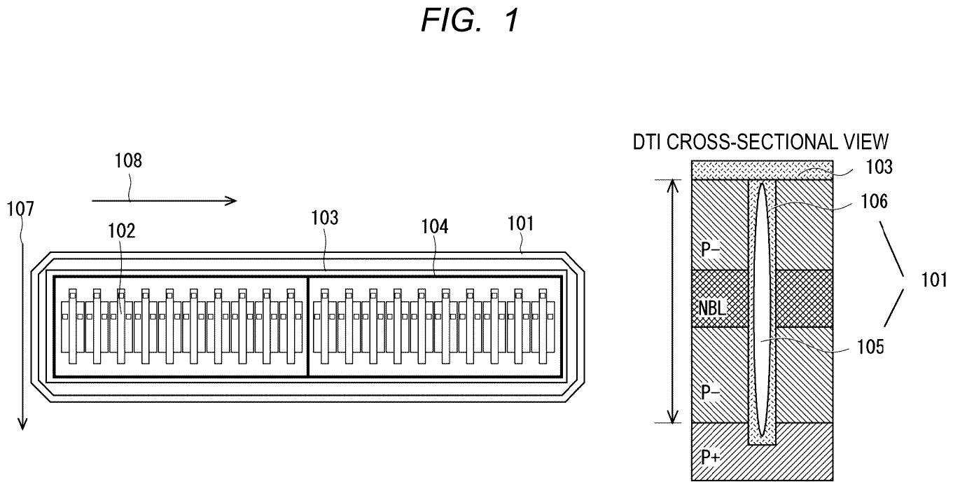

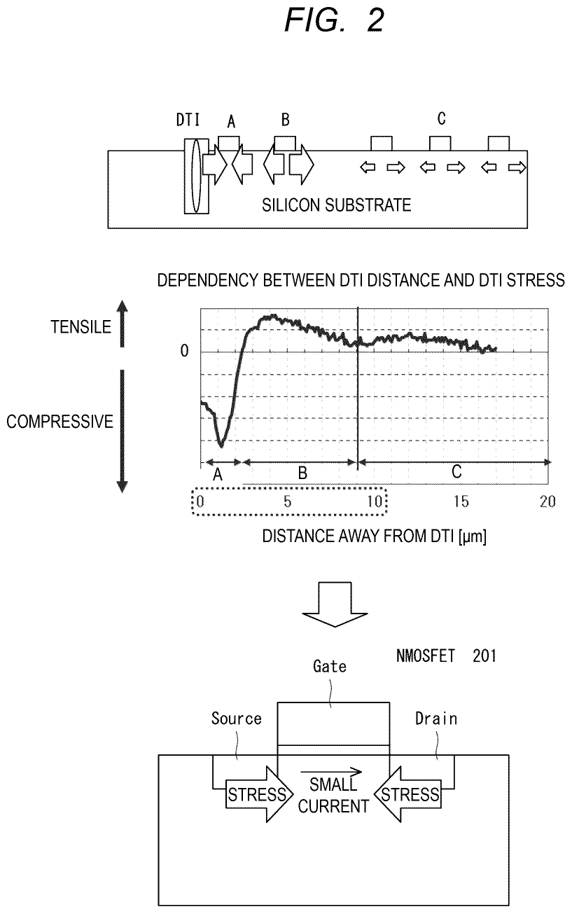

FIG. 1 is a schematic plan view of the deep trench isolation according to the embodiment. FIG. 2 is a diagram showing a stress of the deep trench isolation and an effect of the stress on the MOS transistor according to the embodiment. Referring to FIG. 1 and FIG. 2, the deep trench isolation (DTI) according to the embodiment will be described.

The semiconductor device according to the present embodiment includes, for example, a bipolar transistor, a CMOS (CMOSFET: Complementary Metal Oxide Semiconductor Field Effect Transistor), and a DMOS (DMOSFET: Doubled Diffused Metal Oxide Semiconductor Field Effect Transistor), as semiconductor elements. In order to form the semiconductor device, the semiconductor elements are separated from each other by DTI. In the semiconductor device, not only STI (Shallow Trench Isolation) but also DTI are used to isolate the MOSFET elements in order to realize high withstand voltage and suppress the effect of noises.

As shown in FIG. 1, a semiconductor element 102 is surrounded by a conventional element isolation STI 103. Further, the plurality of semiconductor elements 102 and the element isolation STI 103 are surrounded by a back gate 104. Further, the plurality of semiconductor elements 102, the element isolation STI 103, and the back gate 104 are surrounded by a DTI 101. The DTI 101 includes a first portion and a second portion extending in a first direction 107, and a third portion and a fourth portion extending in a second direction 108. The first direction 107 and the second direction 108 are along the main surface of the semiconductor substrate. The first direction 107 and the second direction 108 intersect each other. The plurality of semiconductor elements 102 are arranged in the second direction 108. The channel width direction to be described later is the first direction 107, and the channel length direction to be described later is the second direction 108.

As shown in the DTI cross-sectional view of FIG. 1, the semiconductor substrate includes the P+semiconductor substrate and the semiconductor layer formed on the P+semiconductor substrate. In the semiconductor substrate, the DTI 101, the semiconductor element 102, the element isolation STI 103, and the back gate 104 are formed. The element isolation STI 103 is formed in a surface of the semiconductor layer (P-layer) where the semiconductor element 102 is formed. The DTI 101 is formed in a trench provided in the semiconductor substrate. The DTI 101 is formed of an oxide film 106 formed on the side surface and the bottom surface of the trench, and a void 105. The DTI 101 penetrates through the P-layer on the surface of the semiconductor layer, the NBL (N+ Buried Layer) and the P-layer to reach the P+ semiconductor substrate. If the DTI 101 functions as an element isolation, the bottom surface of the DTI 101 may be located between NBL and the P+ semiconductor substrate.

The upper diagram of FIG. 2 shows the strength of the stress of the DTI 101 relative to the distance away from the DTI 101 in the second direction 108. As shown in the upper diagram of FIG. 2, in a region (A) from the DTI 101 to 2 to 3 μm, a compressive stress acts on the semiconductor substrate. In a region (B) where the distance away from the DTI 101 is between 3 μm and 10 μm, a tensile stress acts on the semiconductor substrate. In a region (C) 10 μm or more away from the DTI 101, the tensile stress acting on the semiconductor substrate is converged.

As shown in the lower diagram of FIG. 2, the semiconductor element 102 is, for example, an N-channel type MOSFET 201. The N-channel type MOSFET 201 includes a gate electrode, a source region, and a drain region. The source region and the drain region are formed in the semiconductor substrate. The source region and the drain region are regions into which N-type impurities are introduced. The gate electrode is formed on the semiconductor substrate located between the source region and the drain region via a gate dielectric film. As shown in FIG. 1, the gate electrode, the source region, and the drain region extend in the first direction 107. In FIG. 1, the plurality of N-channel type MOSFETs 201 are arranged in the second direction 108. Accordingly, as shown in FIG. 1, the gate electrode, the source region, and the drain region of the N-channel type MOSFET 201, and the DTI 101 are disposed along the second direction 108. The lower diagram of FIG. 2 shows an exemplary compressive stress acting on the N-channel type MOSFET 201. The stresses of the DTI 101 act primarily in the second direction 108. In the N-channel type MOSFET 201, when the compressive stress acts on the channel region in the channel length direction (second direction), the current flowing through the N-channel type MOSFET 201 decreases.

Similarly, in the N-channel type MOSFET 201, when the tensile stress acts on the channel region in the channel length direction (second direction), the current flowing through the N-channel type MOSFET 201 decreases. Therefore, placing the N-channel type MOSFET in the stress acting region causes performance variation or performance degradation of the N-channel type MOSFET.

### Explanation of Semiconductor Device According to First Embodiment

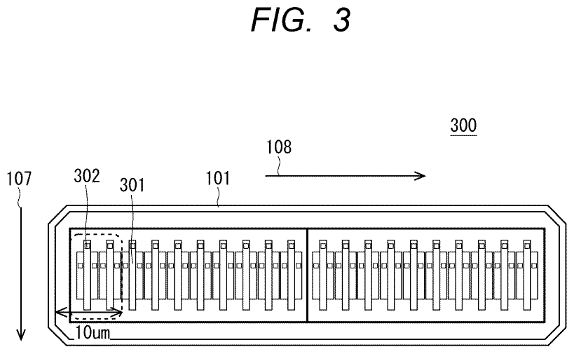

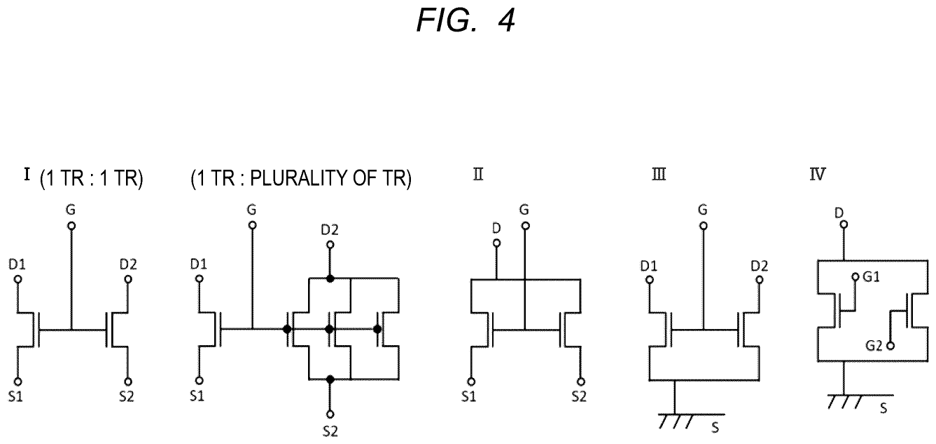

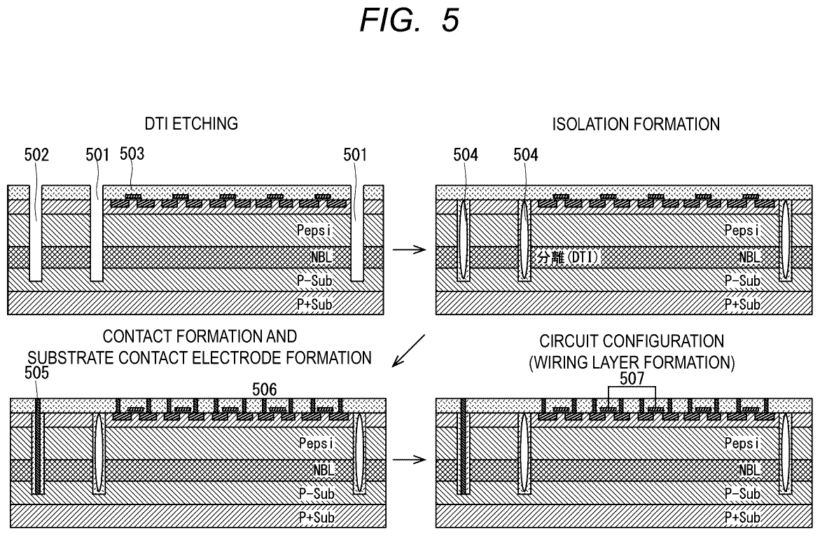

FIG. 3 is a planar layout diagram of the element according to the first embodiment. FIG. 4 is a diagram showing an exemplary configuration of a pair transistor according to the first embodiment. FIG. 5 is a diagram showing a manufacturing method of the pair transistor according to the first embodiment. Referring to FIG. 3 to FIG. 5, the semiconductor device according to the first embodiment will be described.

As shown in FIG. 3, a semiconductor device 300 according to the first embodiment includes a first semiconductor element 301 of an N-channel type MOSFET formed on the semiconductor substrate, and a second semiconductor element 302 of an N-channel type MOSFET formed on the semiconductor substrate and disposed next to the first semiconductor element 301. The semiconductor device 300 further includes the DTI 101 formed in the semiconductor substrate and surrounding the first semiconductor element 301 and the second semiconductor element 302 in plan view.

Each of the first semiconductor element 301 and the second semiconductor element 302 may be one or more. The first semiconductor element 301 and the second semiconductor element 302 are disposed in parallel in the channel length direction. As shown in FIG. 3, the DTI 101 closest to the second semiconductor element 302 in the second direction 108 extends in the first direction 107. In the second direction 108 along the main surface of the semiconductor substrate, the second semiconductor element 302 is disposed between the first semiconductor element 301 and the DTI 101. The DTI 101, the first gate electrode, the first source region and the first drain region of the first semiconductor element 301, the second gate electrode, the second source region and the second drain region of the second semiconductor element 302 are disposed along the second direction 108. The first semiconductor element 301 is 10 μm or more away from the closest DTI 101 in the channel length direction. The second semiconductor element 302 is located 10 μm or less from the closest DTI in the channel length direction. Therefore, the first semiconductor element 301 is formed in a region not affected by the stress of the DTI 101. The second semiconductor element 302 is formed in a region affected by the stress of the DTI 101.

The second semiconductor element 302 is affected by the stress of the DTI 101, and thus has a poor electrical characteristic. However, the first semiconductor element 301 is connected to the first circuit, and the second semiconductor element 302 is connected to the second circuit different from the first circuit. The first circuit and the second circuit are not directly connected. Therefore, the electrical characteristic of the second semiconductor element 302 do not affect the electrical characteristic of the first semiconductor element 301.

The first semiconductor element 301 has a first precision, and the second semiconductor element 302 has a second precision. Since the first semiconductor element 301 is not affected by the stress of the DTI 101, the first precision is higher than the second precision. The first precision is that, for example, the relative precision is 1% or less. The second precision is that, for example, the relative precision is greater than 1%. The relative precision refers to the ratio of the current between the MOSFET of interest and the MOSFET farthest from the DTI 101 in the second direction 108. The MOSFET farthest from the DTI 101 in the second direction 108 is a MOSFET located in the central of the plurality of MOSFETs arranged in the second direction 108 if the number of MOSFETs surrounded by the DTI 101 is an odd number. The MOSFET farthest from the DTI 101 in the second direction 108 is one of the two MOSFET closest to the central of the plurality of MOSFETs arranged in the second direction 108 if the number of MOSFETs surrounded by the DTI 101 is an even number.

An analog signal is handled in an analog circuit. The analog signal whose value is used as is has a greater influence of noise than the digital signal. Therefore, the first circuit using the semiconductor element having high precision can be used in an analog circuit requiring high precision. On the other hand, in a digital circuit, a digital signal is handled. Since it is only necessary to determine whether the digital signal is 0 or 1, the influence of noise is smaller than that of the analog signal. The second circuit to which the semiconductor element having low precision is connected cannot be used for an analog circuit because of large noise, and is preferably used for a digital circuit.

In addition, the first semiconductor element 301 with high precision can configure a pair transistor. The first circuit can be configured by the pair transistor. On the other hand, the second semiconductor element 302 with low precision cannot configure the pair transistor. Therefore, the second circuit is configured by a transistor different from the pair transistor. As shown in FIG. 4, the pair transistor can be exemplified by gate sharing (I), drain sharing (II), source sharing (III), drain and source sharing (IV).

As shown in FIG. 5, the pair transistor is manufactured as follows. First, as shown in DTI etching, after a MOSFET 503 is formed on the semiconductor substrate, a trench 501 for the DTI and a trench 502 for a substrate contact electrode are formed.

Next, an oxide film 504 is formed in the trench 501 for DTI and the trench 502 for substrate contact electrode, and the DTI is formed in the trench 502. The DTI electrically isolates the MOSFET 503 from the other elements. Next, a contact hole is formed in the trench 502 for substrate contact electrode and MOSFET 503, and then a metal or an N-type semiconductor is buried in the trench 502. As a result, a substrate contact electrode 505 is formed in the trench 502, and a source-drain contact electrode 506 of the MOSFET is formed. As the metal, tungsten, molybdenum, or the like can be used. As the N-type semiconductor, N-type polysilicon doped with phosphorus or arsenic can be used.

Finally, a pair transistor 507 is configured by forming a wiring connecting adjacent MOSFET 503 to each other.

In this way, the first semiconductor element 301 configuring the pair transistor can be formed.

### Explanation of Semiconductor Device According to Second Embodiment

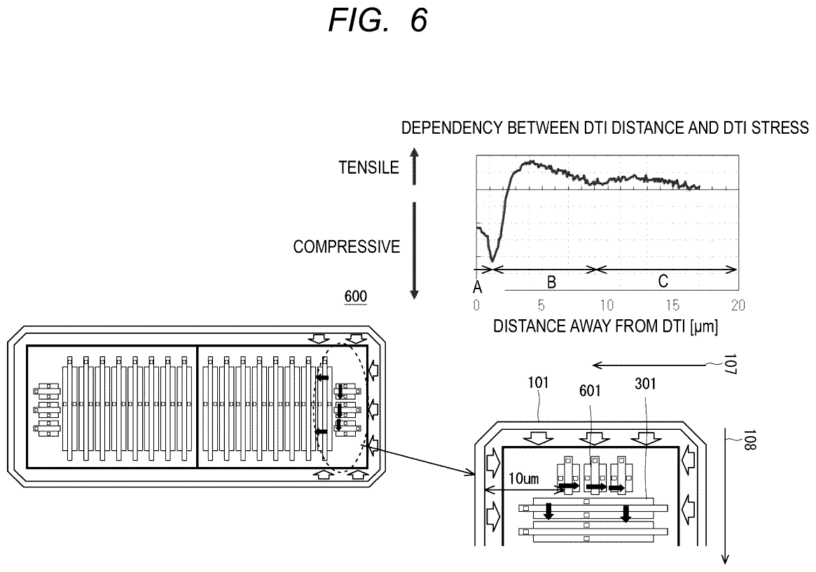

FIG. 6 is a layout diagram of the semiconductor device according to the second embodiment. Referring to FIG. 6, the semiconductor device according to the second embodiment will be described.

In a semiconductor device 600 according to the second embodiment, semiconductor elements having high precision are efficiently disposed. As shown in FIG. 6, the semiconductor device 600 includes the semiconductor substrate, the first semiconductor element 301 formed on the semiconductor substrate and being an N-channel type MOSFET, and a second semiconductor element 601 formed on the semiconductor substrate and being an N-channel type MOSFET disposed next to the first semiconductor element 301. The semiconductor device 600 includes the DTI 101 formed in the semiconductor substrate and surrounding the first semiconductor element 301 and the second semiconductor element 601 in plan view.

Each of the first semiconductor element 301 and the second semiconductor element 601 may be one or more. The second semiconductor element 601 is disposed such that the channel length direction of the second semiconductor element 601 is orthogonal to the channel length direction of the first semiconductor element 301. The channel length direction of the second semiconductor element 601 is a direction in which the DTI 101 closest to the second semiconductor element 601 extends. That is, as shown in FIG. 6, the DTI 101 closest to the second semiconductor element 601 in the second direction 108 extends in the first direction 107. In the second direction 108 along the main surface of the semiconductor substrate, the second semiconductor element 601 is disposed between the first semiconductor element 301 and the DTI 101. The first semiconductor element 301 is 10 μm or more away from the closest DTI 101 in the channel length direction. The second semiconductor element 601 is 10 μm or more away from the closest DTI in the channel length direction. Therefore, the first semiconductor element 301 and the second semiconductor element 601 are formed in a region that is not affected by the stress of the DTI 101.

The second semiconductor element 601 is not affected by the stress of the DTI 101, and therefore has no inferior electrical characteristic. The first semiconductor element 301 and the second semiconductor element 601 have a first precision. The first precision is that, for example, the relative precision is 1% or less.

The first semiconductor element 301 and the second semiconductor element 601 are preferably used in an analog circuit. In addition, the first semiconductor element 301 and the second semiconductor element 601 with high precision can configure a pair transistor.

The second semiconductor element 601 is formed in a region affected by the stress as viewed from the first semiconductor element 301, but it is possible to prevent the second semiconductor element from being affected by the stress of the DTI 101 by devising the layout. Therefore, a large number of highly precise semiconductor elements can be disposed.

### Explanation of Semiconductor Device According to Third Embodiment

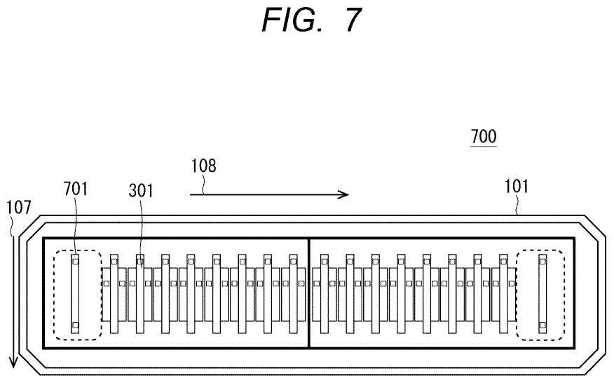

FIG. 7 is a layout diagram of the semiconductor device according to the third embodiment. Referring to FIG. 7, the semiconductor device according to the third embodiment will be described.

In a semiconductor device 700 according to the third embodiment, an element other than the N-channel type MOSFET, for example, a resistor element is disposed in a region affected by stress. As shown in FIG. 7, the semiconductor device 700 includes the semiconductor substrate, the first semiconductor element 301 formed on the semiconductor substrate and being an N-channel type MOSFET, and a resistor element 701 formed on the semiconductor substrate and disposed next to the first semiconductor element 301. The semiconductor device 700 includes the DTI 101 formed in the semiconductor substrate and surrounding the first semiconductor element 301 and the resistor element 701 in plan view.

The number of the first semiconductor element 301 may be one or more. As shown in FIG. 7, the DTI 101 closest to the resistor element 701 in the second direction 108 extends in the first direction 107. In the second direction 108 along the main surface of the semiconductor substrate, the resistor element 701 is disposed between the first semiconductor element 301 and the DTI 101. The first semiconductor element 301 is 10 μm or more away from the closest DTI 101 in the channel length direction.

The resistor element 701 is formed within 10 μm from the closest DTI 101 in the channel length direction of the first semiconductor element 301. Therefore, the first semiconductor element 301 is formed in a region not affected by the stress of the DTI 101. The resistor element 701 is formed in a region affected by the stress of the DTI 101.

The resistor element 701 is formed in the same layer as the gate electrode of the first semiconductor element 301. Therefore, the resistor element 701 is not affected by the stress acting on the semiconductor layer. Therefore, the semiconductor device 700 can effectively utilize the region where a highly precise N-channel type MOSFET cannot be formed.

### Explanation of Semiconductor Device According to Fourth Embodiment

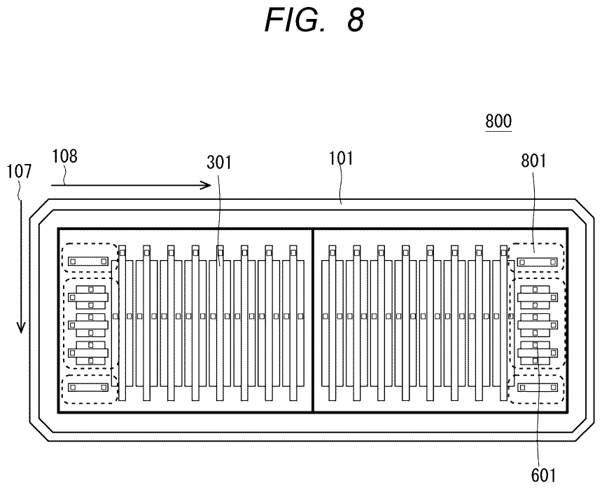

FIG. 8 is a layout diagram of the semiconductor device according to the fourth embodiment. Referring to FIG. 8, the semiconductor device according to the fourth embodiment will be described.

In a semiconductor device 800 according to the fourth embodiment, high precision semiconductor elements are efficiently disposed, and elements other than transistors, for example, resistor element are disposed in a region affected by stress. As shown in FIG. 8, the semiconductor device 800 includes the semiconductor substrate, the first semiconductor element 301 formed on the semiconductor substrate and being an N-channel type MOSFET, the second semiconductor element 601 formed on the semiconductor substrate and being an N-channel type MOSFET disposed next to the first semiconductor element 301, and a resistor element 801 formed in the semiconductor substrate and disposed next to the first semiconductor element 301. The semiconductor device 800 includes the DTI 101 formed in the semiconductor substrate and surrounding the first semiconductor element 301, the second semiconductor element 601, and the resistor element 801 in plan view.

The first semiconductor element 301 and the second semiconductor element 601 are the same as those in the second embodiment, and therefore will not be described. The effect of the layout of the second semiconductor element 601 is the same as the second embodiment. Further, the resistor element 801 is disposed next to the second semiconductor element 601 in the channel length direction (the first direction 107) of the second semiconductor element 601. As shown in FIG. 8, the DTI 101 closest to the second semiconductor element 601 in the first direction 107 extends in the second direction 108. In the first direction 107 along the main surface of the semiconductor substrate, the resistor element 801 is disposed between the second semiconductor element 601 and the DTI 101. The resistor element 801 is disposed within 10 μm from the closest DTI 101 in the channel length direction (first direction 107) of the second semiconductor element 601. Therefore, the resistor element 801 is formed in a region affected by the stress of the DTI 101.

The resistor element 801 is formed in the same layer as the gate electrodes of the first semiconductor element 301 and the second semiconductor element 601. Therefore, the resistor element 801 is not affected by the stress applied to the semiconductor layer. Therefore, the semiconductor device 800 can effectively utilize a region where a highly precise N-channel type MOSFET cannot be formed. That is, the third embodiment can be combined with the second embodiment.

### Explanation of Semiconductor Device According to Fifth Embodiment

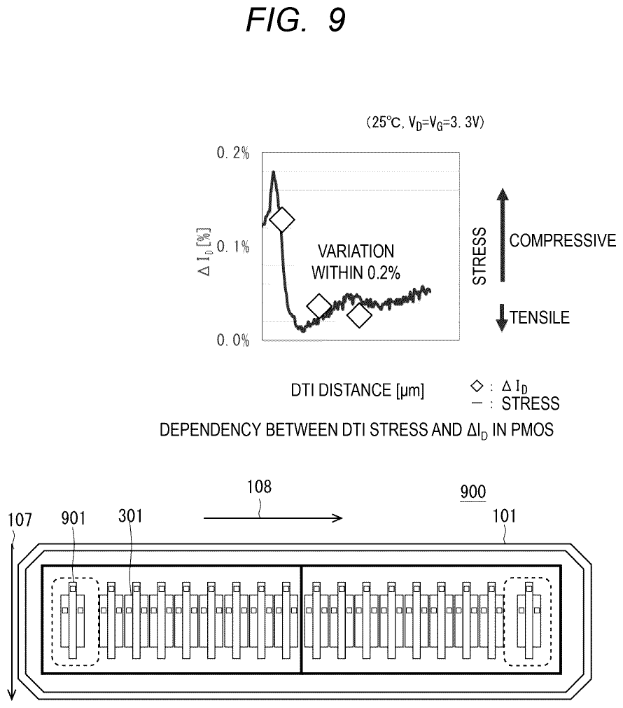

FIG. 9 is a layout diagram of the semiconductor device according to the fifth embodiment. Referring to FIG. 9, the semiconductor device according to the fifth embodiment will be described.

In a semiconductor device 900 according to the fifth embodiment, a P-channel type MOSFET is disposed in a region affected by stress. The upper diagram of FIG. 9 shows variations in the electrical characteristic of the P-channel type MOSFET and the stress with respect to the distance away from the DTI in the second direction 108. As shown in the upper diagram of FIG. 9, the variation in the electrical characteristic of the P-channel type MOSFET is small with respect to the distance away from the DTI 101. The variation of the electrical characteristic of the P-channel type MOSFET is less than 0.2% even in a region with large compressive stress along the channel length direction. Therefore, the highly precise semiconductor device 900 can be obtained even when the P-channel type MOSFET is disposed in a region where the variation in stress is large 10 μm or less from the DTI 101.

As shown in the lower diagram of FIG. 9, the semiconductor device 900 according to the fifth embodiment t includes the semiconductor substrate, the first semiconductor element 301 formed in the semiconductor substrate and being an N-channel type MOSFET, and a second semiconductor element 901 of the P-channel type MOSFET formed in the semiconductor substrate and disposed next to the first t semiconductor element 301. The semiconductor device 900 further includes the DTI 101 formed in the semiconductor substrate and surrounding the first semiconductor element 301 and the second semiconductor element 901 in plan view.

The P-channel type MOSFET includes a gate electrode, a source region, and a drain region. The source region and the drain region are formed in the semiconductor substrate. The source region and the drain region are regions into which P-type impurities are introduced. The gate electrode is formed on the semiconductor substrate located between the source region and the drain region via a gate dielectric film. As shown in FIG. 9, the gate electrode, the source region, and the drain region extend in the first direction 107. In FIG. 9, the plurality of P-channel type MOSFETs are arranged in the second direction 108. Thus, as shown in FIG. 9, the DTI 101, the gate electrode, the source region, and the drain region of the P-channel type MOSFET are disposed along the second direction 108. Thus, the stress of the DTI 101 act primarily in the second direction 108.

Each of the first semiconductor element 301 and the second semiconductor element more. The first semiconductor element 301 and the second semiconductor element 901 are disposed in parallel with each other in the channel length direction. As shown in FIG. 9, the DTI 101 closest to the second semiconductor element 901 in the second direction 108 extends in the first direction 107. In the second direction 108 along the main surface of the semiconductor substrate, the second semiconductor element 901 is disposed between the first semiconductor element 301 and the DTI 101. The first semiconductor element 301 is 10 μm or more away from the closest DTI 101 in the channel length direction. The second semiconductor element 901 is 10 μm or less from the closest DTI in the channel length direction. Therefore, the first semiconductor element 301 is formed in a region not affected by the stress of the DTI 101.

The second semiconductor element 901 is formed in a region affected by the stress of the DTI 101.

Even if the second semiconductor element 901 is formed in a region affected by the stress of the DTI 101, the variation in electrical characteristic of the second semiconductor element 901 is small with respect to the distance from the DTI 101, and thus a highly precise semiconductor device 900 can be obtained.

### Explanation of Semiconductor Device According to Sixth Embodiment

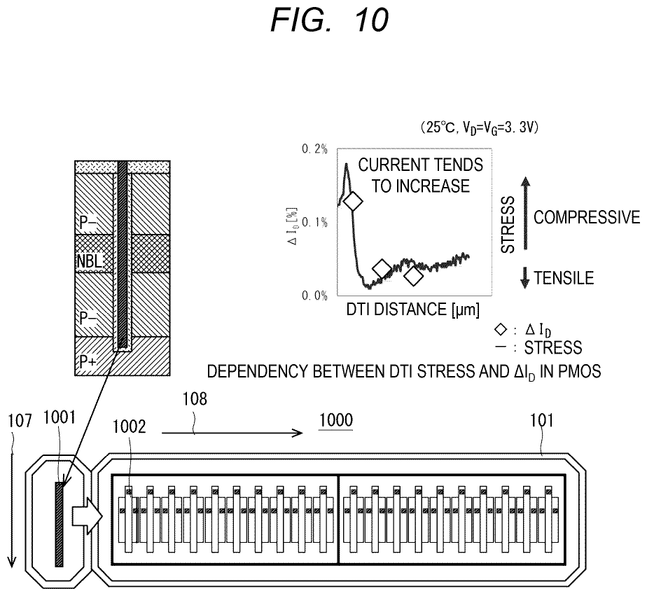

FIG. 10 is a layout diagram of the semiconductor device according to the sixth embodiment. Referring to FIG. 10, the semiconductor device according to the sixth embodiment will be described.

In a semiconductor device 1000 according to the sixth embodiment, the P-channel type MOSFET and a substrate contact electrode 1001 are provided. The substrate contact electrode 1001 is disposed in parallel with the P-channel type MOSFET. Since the substrate contact electrode 1001 generates strong compressive stress, the semiconductor device 1000 according to the sixth embodiment can improve the electrical characteristic of the P-channel type MOSFET. As shown in the upper left cross-sectional view of FIG. 10, the substrate contact electrode 1001 is the DTI of which the void is filled with a conductive material. The stress by the conductive material formed in the trench acts on the substrate contact electrode 1001, so that the compressive stress is stronger than that of DTI. The upper right diagram of FIG. 10 shows variations in the electrical characteristic of the P-channel type MOSFET and the stress with respect to the distance from the DTI. As shown in the upper right diagram of FIG. 10, in the P-channel type MOSFET, when the compressive stress is applied along the channel length direction, the current driving capability is improved. Therefore, in the semiconductor device 1000, the P-channel type MOSFET is disposed in parallel with the substrate contact electrode 1001 to improve the electrical characteristic of the P-channel type MOSFET.

The semiconductor device 1000 according to the sixth embodiment includes the semiconductor substrate, a first semiconductor element 1002 formed on the semiconductor substrate and being a P-channel type MOSFET, and the DTI 101 formed in the semiconductor substrate and surrounding the first semiconductor element 1002 in plan view. As shown in FIG. 10, the gate electrode, the source region, and the drain region of the first semiconductor element 1002 extend in the first direction 107. In FIG. 10, the plurality of P-channel type MOSFETs are disposed in the second direction 108. The semiconductor device 1000 includes the substrate contact electrode 1001 disposed in parallel to the channel width direction of the first direction 107 of the first semiconductor element 1002. The length of the substrate contact electrode 1001 in the first direction 107 parallel to the channel width direction of the first semiconductor element 1002 is longer than the channel width of the first semiconductor element 1002. Thus, the stress of the substrate contact electrode 1001 acts primarily in the second direction 108.

The number of the first semiconductor elements 1002 may be one or more. As shown in the upper left cross-sectional view of FIG. 10, the substrate contact electrode 1001 partially undergo the same forming process as the DTI 101, and thus penetrates through the P-layer on the surface of the semiconductor layer, the NBL (N+ Buried Layer) and the P-layer to reach the P+ semiconductor substrate. By making the length of the substrate contact electrode 1001 in the direction parallel to the channel width direction of the first semiconductor element 1002 longer than the channel width of the first semiconductor element 1002, the entire channel formation region of the first semiconductor element 1002 can be stressed. The channel width of the first semiconductor element 1002 is 0.4 μm to 100 μm. The distance from the substrate contact electrode 1001 to the first semiconductor element 1002 is preferably 5 to 6 μm.

The semiconductor device 1000 can be configured by a high performance P-channel type MOSFET.

### Explanation of Modified Example of Layout of Deep Trench Isolation According to Embodiment

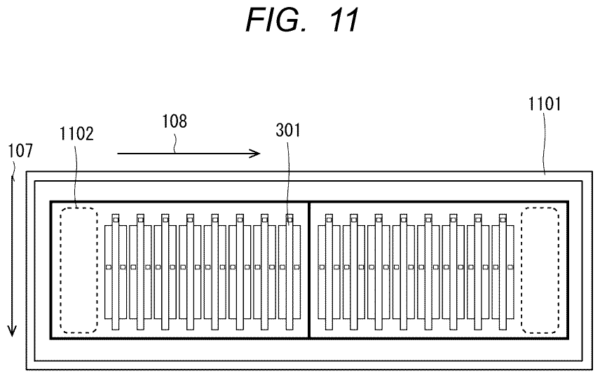

FIG. 11 is a modified example of the layout of the deep trench isolation according to the embodiment. Referring to FIG.

11, the modified example of the layout of the deep trench isolation according to the embodiment will be described.

As shown in FIG. 11, a planar shape of a DTI 1101 in plan view is rectangular in the modified example of the layout of the DTI 1101 according to the embodiment. The DTI 101 has a rectangular corner chamfered in plan view. The DTI 1101 has a rectangular shape leaving corners in plan view.

Even in such cases, a region 1102 to which the stress of the DTI is applied is formed. The region 1102 is a region of 10 μm or less from the DTI 1101 in the second direction 108, which is the channel length direction of the first semiconductor element 301. Therefore, the second semiconductor element 302, the second semiconductor element 601, the first semiconductor element 1002, the resistor element 701, or the resistor element 801 indicated by the first embodiment to the sixth embodiment can be disposed in the region 1102. In this case, the same effects as those described in the respective embodiments can be obtained.

Although the invention made by the inventor has been specifically described based on the embodiment, the present invention is not limited to the embodiment already described, and it is needless to say that various modifications can be made without departing from the gist thereof.

What is claimed is:

1. A semiconductor device comprising:
a semiconductor substrate;
a first semiconductor element formed on the semiconductor substrate, the first semiconductor element being an N-channel type MOSFET;
a second semiconductor element formed on the semiconductor substrate and disposed next to the first semiconductor element, the second semiconductor element being an N-channel type MOSFET; and
a deep trench isolation formed in the semiconductor substrate and surrounding the first semiconductor element and the second semiconductor element in plan view,
wherein the first semiconductor element is connected to a first circuit, and
wherein the second semiconductor element is connected to a second circuit different from the first circuit.

2. The semiconductor device according to claim 1,
wherein the first circuit has a first precision,
wherein the second circuit has a second precision, and
wherein the first precision is higher than the second precision.

3. The semiconductor device according to claim 1,
wherein the first circuit is an analog circuit, and
wherein the second circuit is a digital circuit.

4. The semiconductor device according to claim 1,
wherein the first circuit is configured by a pair transistor, and
wherein the second circuit is configured by a transistor different from the pair transistor.

5. The semiconductor device according to claim 1,
wherein in a first direction along a main surface of the semiconductor substrate, the second semiconductor element is disposed between the first semiconductor element and the deep trench isolation,
wherein the first semiconductor element includes:
a first gate electrode extending in a second direction, the second direction intersecting with the first direction and being along the main surface of the semiconductor substrate;
a first source region; and
a first drain region,
wherein the second semiconductor element includes:
a second gate electrode extending in the second direction;
a second source region; and
a second drain region,
wherein the deep trench isolation extends in the first direction, and
wherein the deep trench isolation, the first gate electrode, the first source region, the first drain region, the second gate electrode, the second source region and the second drain region are disposed in the second direction.

6. The semiconductor device according to claim 1,
wherein in plan view, a planar shape of the deep trench isolation is a rectangle.

7. The semiconductor device according to claim 1,
wherein the first semiconductor element is spaced more than 10 μm apart from the deep trench isolation.

8. The semiconductor device according to claim 1,
wherein the first semiconductor element is formed in a region to which a compressive stress is applied by the deep trench isolation.

9. The semiconductor device according to claim 1,
wherein the semiconductor device includes a bipolar transistor, a CMOS and a DMOS.

10. The semiconductor device according to claim 1,
wherein the deep trench isolation is formed in a trench reaching from a surface of a semiconductor layer to the semiconductor substrate.

11. A semiconductor device comprising:
a semiconductor substrate;
a first semiconductor element formed on the semiconductor substrate, the first semiconductor element being an N-channel type MOSFET;
a second semiconductor element formed on the semiconductor substrate and disposed next to the first semiconductor element, the second semiconductor element being an N-channel type MOSFET; and
a deep trench isolation formed in the semiconductor substrate and surrounding the first semiconductor element and the second semiconductor element in plan view,
wherein the second semiconductor element is disposed such that a channel length direction of the second semiconductor element is orthogonal to a channel length direction of the first semiconductor element, and
wherein the channel length direction of the second semiconductor element is an extending direction of the deep trench isolation closest to the second semiconductor element.

12. The semiconductor device according to claim 11,
wherein in plan view, a planar shape of the deep trench isolation is a rectangle.

13. The semiconductor device according to claim 11,
wherein the first semiconductor element is spaced more than 10 μm apart from the deep trench isolation.

14. The semiconductor device according to claim 11,
wherein the first semiconductor element is formed in a region to which a compressive stress is applied by the deep trench isolation.

15. The semiconductor device according to claim 11,
wherein the semiconductor device includes a bipolar transistor, a CMOS and a DMOS.

16. The semiconductor device according to claim 11,
wherein the deep trench isolation is formed in a trench reaching from a surface of a semiconductor layer to the semiconductor substrate.
